(19) United States
(12) Patent Application Publication
(10) Pub. No.: US 2005/0153518 A1
(43) Pub. Date: Jul. 14, 2005

(54) Method for forming capacitor using etching stopper film in semiconductor memory

(75) Inventors: Young-Sub You, Pyoungtack-si (KR); Jung-Hwan Oh, Suwon-si (KR); Ki-Su Na, Yongin-si (KR); Seok-Woo Nam, Yongin-si (KR); Hun-Hyeoung Leam, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/012,403

(22) Filed: Dec. 15, 2004

(30) Foreign Application Priority Data
Jan. 9, 2004 (KR) 2004-1454

(51) Int. Cl. H01L 21/8242; H01L 21/20

(52) U.S. Cl. 438/397

(57) ABSTRACT

A method for forming a capacitor comprises forming a supporting insulating film, an etching stopper film made of alumina series or hafnium oxide series, and a mold insulating film on a surface of a semiconductor substrate having a first structure including conductive plugs surrounded by a first insulating film, patterning the mold insulating film, the etching stopper film and the supporting insulating film to form openings that expose the conductive plugs, forming a storage node conductive film electrically connected to the conductive plugs on the surface of the semiconductor substrate having the openings formed therein and concurrently annealing the etching stopper film, separating the storage node conductive film to form a plurality of storage nodes, exposing at least a part of an outer surface of the storage node by selectively etching remaining mold insulating film, which is exposed by the separated storage node conductive film, until the etching stopper film is exposed, and forming a plurality of plate nodes on the plurality of storage nodes with a dielectric film disposed therebetween.

### CROSS-REFERENCE TO RELATED APPLICATION

This application claims priority to Korean Patent Application No. 2004-1454, filed on Jan. 9, 2004, the disclosure of which is hereby incorporated herein by reference in its entirety.

### BACKGROUND

1. Technical Field

The present disclosure relates to a method for forming a semiconductor device and, more particularly, to a method for forming a capacitor through the formation of an etching stopper film of hafnium oxide series or alumina series.

2. Discussion of Related Art

Generally, a memory cell in a dynamic random access memory (DRAM) includes an access transistor and a storage capacitor. The storage capacitor includes a stacked capacitor and a trench capacitor according to a position in which the storage capacitor is formed in a semiconductor substrate. In a semiconductor memory, it is preferable for the stacked capacitor to have a large capacitance within a limited area. The large capacitance within a limited area can provide a refresh operation period within a certain value. A small critical dimension (CD) due to high integration of the memory cell results in lower capacitance.

With the increasing integration of semiconductor memories, a pattern size of a capacitor, which normally comprises a storage node as a lower electrode and a plate node as an upper electrode, becomes smaller. The storage node will correspondingly have a small bottom critical dimension. The small bottom critical dimension of the storage node will cause a leaning phenomenon in a fabrication process, where the maintenance of an original pattern is not secured and the lower electrode of the capacitor may fall down.

FIG. 1 is a cross-sectional view illustrating the storage node that is a lower electrode of a capacitor formed by a conventional method. As shown in FIG. 1, storage nodes 26 are formed on a semiconductor substrate 10 having transistors and bit lines. The storage nodes 26 are electrically connected to storage node contact plugs 14 surrounded by an insulating film 12. The storage nodes 26 are formed in a small critical dimension and in a large height. Therefore, a leaning phenomenon easily occurs.

FIG. 2 is a scanning electronic microscope (SEM) photograph showing the leaning phenomenon of the above-stated storage nodes. This leaning phenomenon causes an electrical short of a lower electrode in the capacitor, thereby resulting in a failure of a circuit. A conventional method for preventing the leaning phenomenon is a method for forming a support layer so that the storage nodes do not fall down upon forming the storage nodes.

Forming a capacitor through the formation of the support layer is disclosed in Korean Laid-open Patent No. 2003-0063811 entitled “Stacked capacitor for a semiconductor device and a method of fabricating the same,” Dong-Gun Park and also in U.S. Publication No. 2003/0136996 claiming priority from the Korean Patent Application.

Processes for the formation of the conventional capacitor includes a process of forming an etching stopper film and an insulating film on a support layer in sequence, and removing the insulating film using an etching process after separation of nodes. The insulating film can be formed of an oxide film. A wet etching process is typically employed to remove the oxide film. A silicon nitride film can be used as an etching stopper film that may be introduced beneath the oxide film or on the support layer to control the wet etching.

When the silicon nitride film is used as the etching stopper film, the support layer introduced beneath the etching stopper film may be damaged by a wet etching process of removing the oxide film. That is, an etching solution used in the wet etching may diffuse into the underlying insulating film along an interface between the silicon nitride film and the storage electrode, thereby melting the underlying insulating film. This phenomenon is largely caused due to a poor bonding feature between the silicon nitride film and the metal electrode.

Since the insulating film, which forms the support layer, beneath the above-described etching stopper film supports the storage electrodes, the melting of the underlying insulating film may cause an electrode defect, i.e., falling down or leaning of the storage electrode. Therefore, there is a need for a new etching terminating film for preventing the insulating film beneath the etching terminating film from being eroded by the etching solution.

### SUMMARY OF THE INVENTION

In an exemplary embodiment of the present invention, a method for forming a capacitor comprises forming a supporting insulating film, an etching stopper film made of alumina series or hafnium oxide series, and a mold insulating film on a surface of a semiconductor substrate having a first structure including conductive plugs surrounded by a first insulating film, patterning the mold insulating film, the etching stopper film and the supporting insulating film to form openings that expose the conductive plugs, forming a storage node conductive film electrically connected to the conductive plugs on the surface of the semiconductor substrate having the openings formed therein and concurrently annealing the etching stopper film, separating the storage node conductive film to form a plurality of storage nodes, exposing at least a part of an outer surface of the storage node by selectively etching remaining mold insulating film, which is exposed by the separated storage node conductive film, until the etching stopper film is exposed, and forming a plurality of plate nodes on the plurality of storage nodes with a dielectric film disposed therebetween.

In another exemplary embodiment of the present invention, a method for forming a capacitor comprises forming a supporting insulating film, an etching stopper film made of alumina series or hafnium oxide series, and a mold insulating film on a surface of a semiconductor substrate having a first structure including conductive plugs surrounded by a first insulating film, patterning the mold insulating film, the etching stopper film and the supporting insulating film to form openings that expose the conductive plugs, forming a conductive film electrically connected to the conductivity plugs on the surface of the semiconductor substrate having the openings formed therein, the conductive film being formed along an inner surface of the openings, and concurrently annealing the etching stopper film, forming an artificial insulating film on the surface of the semiconductor substrate having the conductive film formed thereon to fill the openings, separating a plurality of storage nodes by performing a planarization process on the surface of the semiconductor substrate having the artificial insulating film formed thereon until the mold insulating film is exposed, selectively etching the exposed mold insulating film until the etching stopper film is exposed and concurrently etching and removing the artificial insulating film to expose at least a part of the storage nodes, and forming a plurality of plate nodes on the plurality of storage nodes with a dielectric film disposed therebetween.

In still another exemplary embodiment of the present invention, a method for forming an etching stopper film for controlling an oxide film etch in an etching process for the fabrication of a semiconductor device includes forming a film of hafnium oxide series or alumina series, and annealing the film of the hafnium oxide series or alumina series.

These and other exemplary embodiments, features and advantages of the present invention will become more apparent by describing in detail exemplary embodiments thereof with reference to the attached drawings.

### BRIEF DESCRIPTION OF THE DRAWINGS

FIG. 1 is a cross-sectional view illustrating a storage node formed by a conventional method.

FIG. 2 is a scanning electronic microscope photograph of the storage node in FIG. 1.

FIGS. 3 to 8 are cross-sectional views schematically illustrating a method for forming a capacitor according to an exemplary embodiment of the present invention.

FIGS. 9 to 11 are scanning electronic microscope photographs of the storage node in FIGS. 3 to 8.

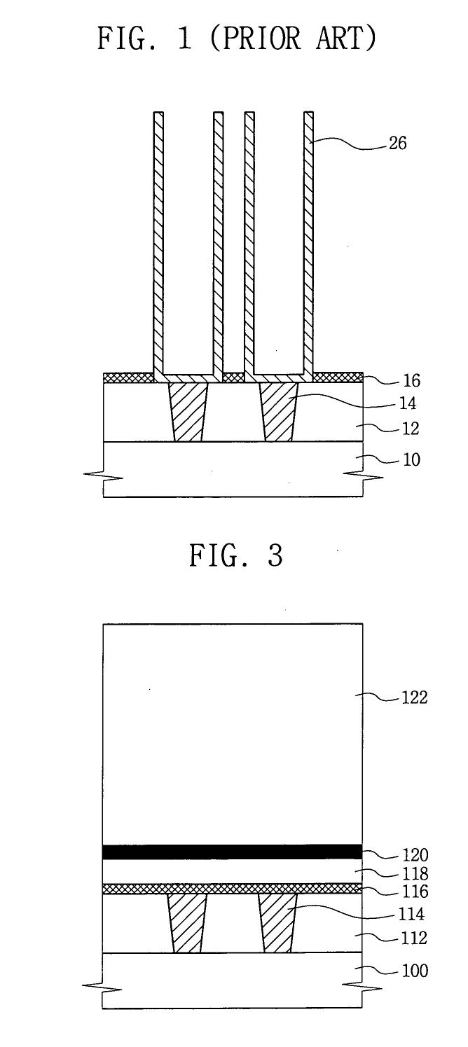

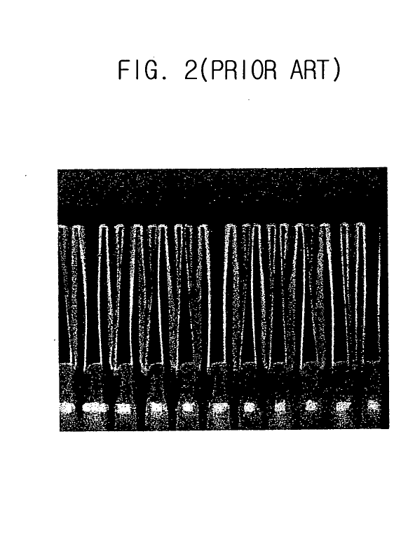

### DETAILED DESCRIPTION OF EXEMPLARY EMBODIMENTS

Exemplary embodiments of the present invention will now be described more fully with reference to the accompanying drawings. This disclosure may, however, be embodied in many different forms and should not be construed as being limited to the embodiments set forth herein. Rather, these embodiments are provided so that this disclosure will be through and complete, and will fully convey the concept of the invention to those skilled in the art.

In an exemplary embodiment of the present invention, a new etching stopper film of hafnium oxide series or alumina series may control an oxide film etching process applied to a method for forming a capacitor. In another exemplary embodiment of the present invention, the etching stopper film may also be applied to fabrication processes other than the capacitor formation process with a different process condition.

FIGS. 3 to 8 are cross-sectional views schematically illustrating a method for forming a capacitor according to an exemplary embodiment of the present invention. As shown in FIG. 3, conductive plugs 114 to be electrically connected to storage nodes are formed on a semiconductor substrate 100 using a conventional storage node contact process or buried contact process. The conductive plugs 114 are surrounded by an interlayer insulating film 112. The conductive plugs 114 are insulated from other conductive patterns (not shown), such as, for example, a gate, formed on the semiconductor substrate 100. The conductive plugs 114 are electrically connected to an active region of the semiconductor substrate 100. The conductive plugs 114 may be formed from several conductive materials. For example, they may be formed from a conductive polysilicon.

The conductive plugs 114 are formed on the semiconductor substrate 100 having a lower structure including transistors, bit lines and the like formed thereon. A first etching stopper film 116 is formed on the conductive plugs 114. The first etching stopper film 116 may be formed of a nitride film, and is used as an etching stopper film when openings are formed for the formation of storage nodes in a subsequent process. A supporting insulating film 118 is formed on the first etching stopper film 116. The supporting insulating film 118 supports a storage electrode, which will be formed in a subsequent process, so that the storage electrode does not fall down or collapse. The supporting insulating film 118 may be formed of an insulating material typically used to fabricate a semiconductor device. For example, the supporting insulating film 118 is formed by depositing a borophosphosilicate glass (BPSG) or plasma oxide film on the interlayer insulating film 112 to cover the conductive plugs 114. The supporting insulating film 118 should be formed in a thickness that is sufficient to support the storage electrode. For example, it may be formed in a thickness of about 500 Å to about 5000 Å.

A second etching stopper film 120, which will be used in a subsequent etching process, is formed on the supporting insulating film 118. In an exemplary embodiment of the present invention, the second etching stopper film 120 is formed from hafnium oxide (HfO₂) series or alumina (Al₂O₃) series. It is preferable that the second etching stopper film 120 is formed on the supporting insulating film 118 in a thickness that is sufficient to support the storage node using a sputtering method such as, for example, a chemical vapour deposition (CVD) method. For example, the second etching stopper film 120 may be formed in a thickness of about 10 Å to about 200 Å. Alternatively, the second etching stopper film 120 may be formed in a different thickness depending on a subsequent etching process.

A mold insulating film 122 is formed on the second etching stopper film 120. The mold insulating film 122 serves to determine a height of the storage nodes patterned in a subsequent process. In an embodiment of the present invention, the thickness of the mold insulating film 122 can be set depending upon the height of the storage nodes. For example, a single film or a multi-layered film having a thickness of about 10000 Å to about 25000 Å can be the mold insulating film 122. The single film or the multi-layered film can be selected from a BPSG film, a plasma enhanced-tetraethylortho silicate (PE-TEOS) film, a plasma oxide film, and a high-density plasma (HDP) oxide film.

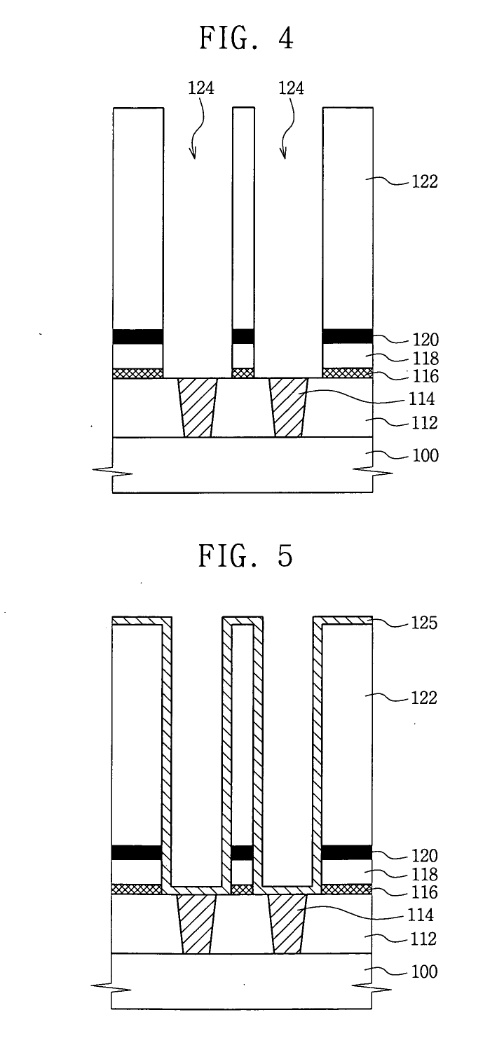

As shown in FIG. 4, to form openings 124 for the formation of the storage nodes, the mold insulating film 122, the second etching stopper film 120, and the supporting insulating film 118 may be patterned using a selective dry etching method. An etching mask (not shown), such as a photoresist pattern can be formed on the mold insulating film 122 using a photolithography process. The mold insulating film 122, the second etching stopper film 120, and the supporting insulating film 118 are etched in sequence. The second etching stopper film 120 may not function as an etching stopper film in the dry etching process because the second etching stopper film 120 is not annealed. The etching process may be conducted until the first etching stopper film 116 is exposed. The openings 124 may be formed by removing the first etching stopper film 116. The openings 124 expose the conductivity plugs 114.

As shown in FIG. 5, a storage node conductive film 125 is formed on the surface of the semiconductor substrate having the openings 124 formed therein. A thickness for the storage node conductive film 125 may be changed. For example, if the storage electrode is formed in a shape of a cylinder, a concave portion can be created by the shape of the openings 124 since the storage node conductive film 125 is deposited along an inner surface of the openings 124. The storage conductive film 125 is formed to be electrically connected to the underlying conductivity plugs 114. The storage node conductive film 125 may be formed of a metal film to increase a capacitance of the capacitor. For example, the storage node conductive film 125 may be formed of any one selected from metal films, such as, for example, a titanium nitride (TiN) film, a titanium aluminum nitride (TiAIN) film, a tantalum nitride (TaN) film, a tungsten nitride (WN) film, a platinum (Pt) film, a ruthenium (Ru) film, an iridium (IR) film, a ruthenium oxide (RuO₂) film, a strontium ruthenium oxide (SrRuO₃) film. In another embodiment of the present invention, the storage node conductive film 125 may be formed of a conductivity polysilicon film.

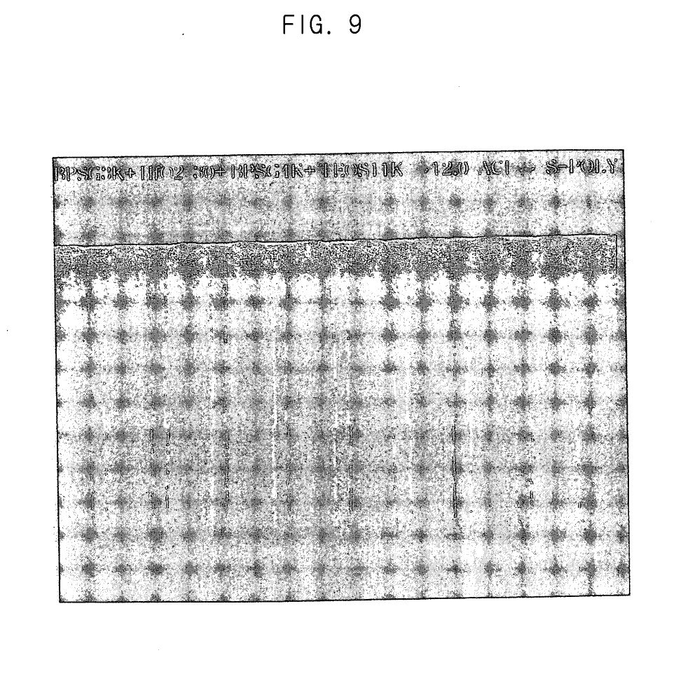

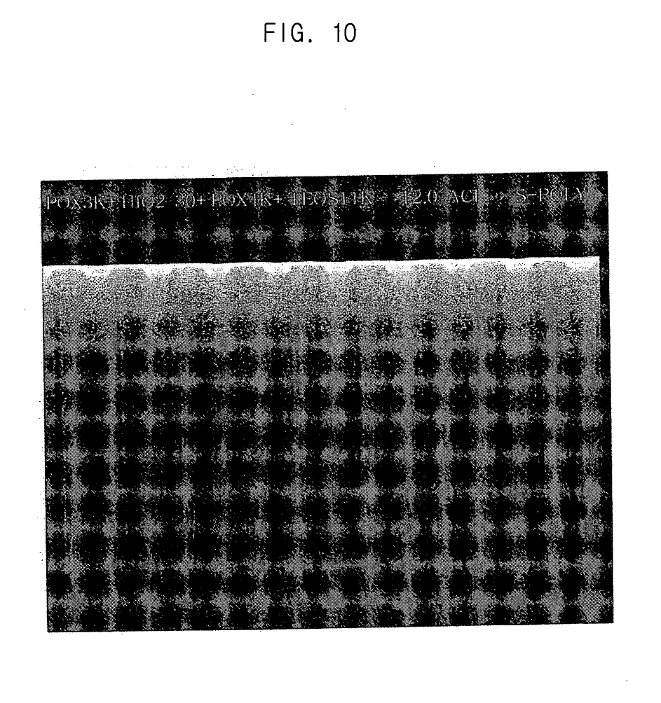

FIG. 9 shows a SEM photograph according to an exemplary embodiment of the present invention. The mold insulating film 122 as a multi-layered film can be formed using BPSG or TEOS. The storage node conductive film 125 is deposited through the formation of the openings 124, wherein the mold insulating film 122 can be made by forming the supporting insulating film 118 of BPSG in a thickness of about 3000 Å. The second etching stopper film 120 of hafnium oxide can be formed in a thickness of about 30 Å on the supporting insulating film 118. The BPSG can be formed in a thickness of about 4000 Å. The TEOS can be formed in a thickness of about 11000 Å on the BPSG.

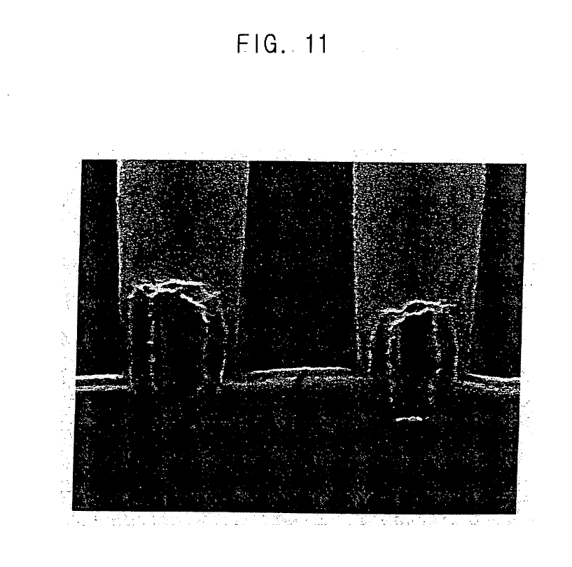

FIG. 10 shows a SEM photograph according to an exemplary embodiment of the present invention. The mold insulating film 122 as a multi-layered film is formed using a plasma oxide film and the TEOS. The storage node conductive film 125 is deposited through the openings. The mold insulating film 122 can be made by forming the supporting insulating film 118 of the plasma oxide film in a thickness of about 3000 Å. The second etching stopper film of hafnium oxide in a thickness of about 30 Å can be formed on the supporting insulating film 118. The plasma oxide film in a thickness of about 4000 Å is formed on the supporting insulating film. The TEOS in a thickness of about 11000 Å is formed on the plasma oxide film.

In one exemplary embodiment of the present invention, the second etching stopper film 120 is annealed by the temperature created upon the formation of the storage node conductive film 125. The second etching stopper film 120 including hafnium oxide series can be annealed at a temperature of about 400° C. to about 600° C. The etching stopper film including alumina series can be annealed at a temperature of about 700° C. to about 900° C.

The above-described annealing process can be automatically conducted when the storage node conductive film 125 is formed. An additional annealing process may not be required. The film of hafnium oxide series or alumina series formed as the second etching stopper film 120 generally has the same etching ratio to the etching solution when the annealing process is not conducted. When the annealing process is conducted, the second etching stopper film 120 may have a different etching ratio, thereby preventing intrusion of a wet etching solution.

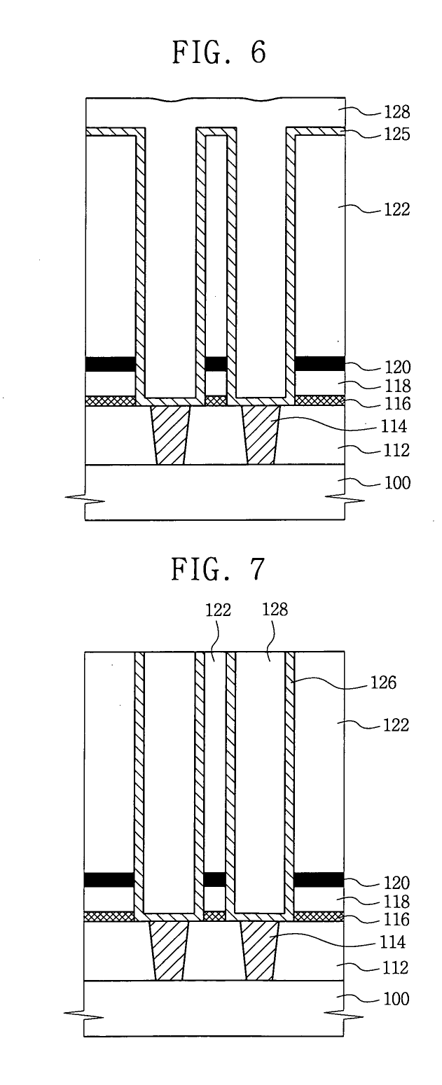

As shown in FIG. 6, an artificial insulating film 128 is formed on the storage node conductive film 125. A planarization process such as a CMP or an etch back may be performed on the artificial insulating film 128. The artificial insulating film 128 is formed on the storage node conductive film 125 and fills the concave portion of the resultant product having the storage node conductive film 125. The artificial insulating film 128 is used to separate each of the storage node conductive film 125. The artificial insulating film needs to be removed in a subsequent process. The artificial insulating film 128 may be formed using a variety of insulating materials. For example, it may be formed of any one selected from a BPSG film, a PE-TEOS film, a plasma oxide film, and a high density plasma oxide film. When the storage node is formed into a stacked type, the artificial insulating film 128 formation process may be omitted.

As shown in FIG. 7, the artificial insulating film 128 is planarized. For example, the artificial insulating film 128 is planarized using the CMP. Alternatively, it may be planarized using the etch back process. In an exemplary embodiment of the present invention, the CMP or the etch back process is performed until the mold insulating film 122 is exposed. Accordingly, a part of the storage node conductive film 125 on the mold insulating film 122 beneath the artificial insulating film 128 is removed so that the storage node 126 is formed. The storage node conductive film 125 portion deposited along an inner surface of the openings (124 of FIG. 4) remains, thereby constituting the storage nodes 126.

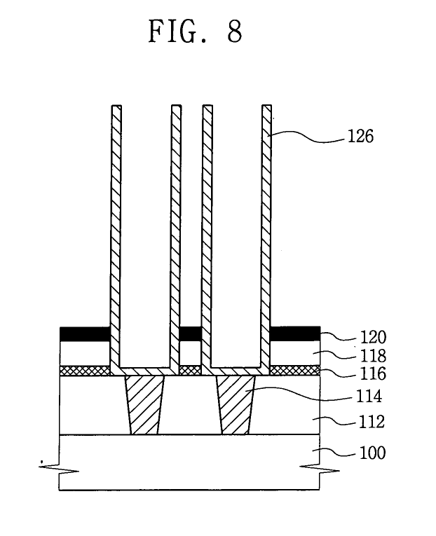

As shown in FIG. 8, the exposed mold insulating film 122 (shown in FIG. 7) and remaining artificial insulating film 128 (shown in FIG. 7) on the concave portion of the storage node 126 are selectively removed by a wet etching process. An etching solution used in a typical selective wet etching process may be used. For example, the mold insulating film 122 and the artificial insulating film 128 may be selectively wet-etched using an etching solution including an LAL solution or a HF solution.

In the wet etching process, the wet etching is terminated and controlled by the second underlying etching stopper film 120 formed from the hafnium oxide series or alumina series. The penetration of the etching solution into the underlying supporting insulating film 118 and the underlying interlayer insulating film 112, via an interface between the second etching stopper film 120 and the storage node 126 is suppressed.

FIG. 11 is a SEM photograph showing a resultant structure after a film of hafnium oxide series or alumina series is used as the termination of the wet etching according to an exemplary embodiment of the present invention. As shown in FIG. 11, the intrusion of the etching solution into the underlying supporting insulating film or interlayer insulating film can be prevented. The etching solution from soaking into or eroding the underlying supporting insulating film 118 or lower interlayer insulating film 112 can be prevented by using hafnium oxide series or aluminum series. A dielectric film is formed on the storage nodes 126. Plate nodes, i.e. an upper electrode of the capacitor, are formed thereon, thereby completing the capacitor.

According to exemplary embodiments of the present invention, melting of the supporting insulating film and the underlying interlayer insulating film under the etching stopper film can be prevented by disposing the etching stopper film of hafnium oxide series or alumina series during the wet etching process. The wet etching process removes the mold insulating film to form the capacitor using, for example, the mold insulating film and the artificial insulating film. The leaning phenomenon of the storage nodes (i.e., the lower electrodes of the capacitors) can be prevented or minimized.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the present invention.

1. A method for forming a capacitor, comprising the steps of:
forming a supporting insulating film, an etching stopper film made of alumina series or hafnium oxide series, and a mold insulating film on a surface of a semiconductor substrate having a first structure including conductive plugs surrounded by a first insulating film;
patterning the mold insulating film, the etching stopper film and the supporting insulating film to form openings that expose the conductive plugs;
forming a storage node conductive film electrically connected to the conductive plugs on the surface of the semiconductor substrate having the openings formed therein and concurrently annealing the etching stopper film;
separating the storage node conductive film to form a plurality of storage nodes;
exposing at least a part of an outer surface of the storage node by selectively etching remaining mold insulating film, which is exposed by the separated storage node conductive film, until the etching stopper film is exposed; and
forming a plurality of plate nodes on the plurality of storage nodes with a dielectric film disposed therebetween.

2. The method according to claim 1, wherein the storage node conductive film is formed to fill the openings, and the separation of the storage node conductive film is performed by a process of planarizing the storage node conductive film until the mold insulating film is exposed.

3. The method according to claim 2, wherein the storage node conductive film is formed along an inner surface of the openings, the separation of the storage node conductive film is performed by a process of forming an artificial insulating film for filling a concave portion of the openings on the surface of the semiconductor substrate having the storage node conductive film formed thereon and then planarizing the surface of the semiconductor substrate having the artificial insulating film formed thereon until the mold insulating film is exposed, and the etching process is performed to etch the artificial insulating film concurrently upon etching the mold insulating film.

4. The method according to claim 3, wherein the supporting insulating film is one of a BPSG film and a plasma oxide film.

5. The method according to claim 4, wherein each of the mold insulating film and the artificial insulating film is a single film or a multi-layered film comprising one or more films selected from a group of insulating films including a BPSG film, a PE-TEOS film, a plasma oxide film, and a high density plasma oxide film.

6. The method according to claim 1, wherein the storage node conductive film is made from a group of conductive films including a titanium nitride film, an aluminum nitride film, a tungsten nitride film, a platinum film, a ruthenium film, an iridium film, a ruthenium oxide film, a strontium ruthenium oxide film, and a conductive polysilicon film.

7. The method according to claim 1, wherein the patterning to form the openings is performed by an anisotropic dry etching process.

8. The method according to claim 2, wherein at least one of a chemical-mechanical polishing process and an etch back process is used as the process of planarizing the storage node conductive film.

9. The method according to claim 3, wherein the mold insulating film and the artificial insulating film is formed by a wet etching process.

10. The method according to claim 1, wherein the supporting insulating film has a thickness of about 500 Å to about 5000 Å.

11. The method according to claim 1, wherein the etching stopper film has a thickness of about 10 Å to about 200 Å.

12. The method according to claim 1, wherein the mold insulating film has a thickness of about 10000 Å to about 25000 Å.

13. The method according to claim 1, further comprising:
a process of forming an etching stopper film for controlling a dry etch for forming the opening prior to forming the supporting insulating film; and
a process of removing the etching stopper film for controlling the dry etch upon forming the opening.

14. The method according to claim 13, wherein the etching stopper film for controlling the dry etch is a nitride film.

15. A method for forming a capacitor, comprising the steps of:
forming a supporting insulating film, an etching stopper film made of alumina series or hafnium oxide series, and a mold insulating film on a surface of a semiconductor substrate having a first structure including conductive plugs surrounded by a first insulating film;
patterning the mold insulating film, the etching stopper film and the supporting insulating film to form openings that expose the conductive plugs;
forming a conductive film electrically connected to the conductivity plugs on the surface of the semiconductor substrate having the openings formed therein, the conductive film being formed along an inner surface of the openings, and concurrently annealing the etching stopper film;
forming an artificial insulating film on the surface of the semiconductor substrate having the conductive film formed thereon to fill the openings;
separating a plurality of storage nodes by performing a planarization process on the surface of the semiconductor substrate having the artificial insulating film formed thereon until the mold insulating film is exposed;
selectively etching the exposed mold insulating film until the etching stopper film is exposed and concurrently etching and removing the artificial insulating film to expose at least a part of the storage nodes; and
forming a plurality of plate nodes on the plurality of storage nodes with a dielectric film disposed therebetween

16. The method according to claim 15, wherein each of the mold insulating film and the artificial insulating film is a single film or a multi-layered film comprising one or more films selected from a group of insulating films including a BPSG film, a PE-TEOS film, a plasma oxide film, and a high density plasma oxide film.

17. The method according to claim 15, wherein the conductive film for forming the plurality of storage nodes is selected from a group of conductive films including a titanium nitride film, an aluminum nitride film, a tungsten nitride film, a platinum film, a ruthenium film, an iridium film, a ruthenium oxide film, a strontium ruthenium oxide film, and a conductive polysilicon film.

18. The method according to claim 15, wherein the mold insulating film and the artificial insulating film are performed by a wet etching process.

19. A method for forming an etching stopper film for controlling an oxide film etch in an etching process for the fabrication of a semiconductor device, the method including steps of:
forming a film of hafnium oxide series or alumina series; and
annealing the film of the hafnium oxide series or alumina series.

20. The method according to claim 19, wherein the oxide film etch is performed by a wet etching process.

21. The method according to claim 20, wherein the annealing the film of the hafnium oxide series is conducted at a temperature of about 400° C. to about 600° C.

22. The method according to claim 20, wherein the annealing the film of the alumina series is conducted at a temperature of about 700° C. to about 900° C.

23. The method according to claim 21, wherein the oxide film is a single film or a multi-layered film comprising one or more films selected from a group of insulating films including a BPSG film, a PE-TEOS film, a plasma oxide film, and a high density plasma oxide film.
